(19) United States
(12) Patent Application Publication
(10) Pub. No.: US 2014/0042342 A1
(43) Pub. Date: Feb. 13, 2014

(54) FLASH LAMPS IN A CONTINUOUS MOTION PROCESS

(71) Applicant: Xenon Corporation, Wilmington, MA (US)

(72) Inventors: Rezaoul KARIM, Medford, MA (US); Saad AHMED, Wilmington, MA (US)

(73) Assignee: XENON CORPORATION, Wilmington, MA (US)

(21) Appl. No.: 13/964,838

(22) Filed: Aug. 12, 2013

Related U.S. Application Data
(60) Provisional application No. 61/681,984, filed on Aug. 10, 2012.

(51) Int. Cl. B01J 19/12; H05K 3/40

(52) U.S. Cl. CPC B01J 19/122; H05K 3/40
USPC 250/492.1; 29/843

(57) ABSTRACT

A system controls a group of flash lamps to provide energy to a work product in a continuous motion processes. The system can identify optimal relationships among various parameters, including the speed of the target material, the physical spacing of the flash lamps, the pulse frequency, and the flash sequence of the lamps. The systems can respond to changes in conditions to automatically adjust parameters. These systems can be applied to design practical sintering, annealing, and/or curing systems.

### CROSS-REFERENCE TO RELATED APPLICATIONS

This application claims priority under §119(e) to U.S. Provisional Application No. 61/681,984, entitled “Flash Lamps in a Continuous Motion Process,” filed Aug. 10, 2012; the contents of which is incorporated by reference herein in its entirety and for all purposes.

### BACKGROUND

There are applications where it can be desirable to use a flash lamp on a sheet of material for sintering, annealing, or otherwise treating a sheet. This treatment can be performed by providing a number of flash lamps that provide a wide footprint (area where energy is received), such as with an elongated U-shaped lamp, and flashed rapidly with low energy per pulse. This approach can ensure that all parts of the sheet are treated with a sufficient amount of energy, although it can be wasteful of energy and not adaptive.

### SUMMARY

This disclosure relates to a system designed to apply a group of flash lamps to a workpiece in a continuous motion processes, including workpieces with a sheet-like form as well as individual, separated components. The system can identify optimal relationships among various parameters, including one or more of the speed of the target material (workpiece), a delay parameter, the physical spacing of the flash lamps, lamp footprint, lamp pitch, percent of lamp overlap, pulse frequency, and the flash sequence of the lamps.

The systems and methods include the ability to dynamically alter one or more parameters in response to a change in conditions. This change can result, for example, from a lamp becoming disabled, a change in conveyor speed, or a change in the output result, such as a change measured by a sensor.

This disclosure further shows how this system can be applied to design practical sintering/annealing/curing systems. This can include providing flashes with relatively high energy at relatively low frequency, such as less than 50 Hz, or further less than 10 Hz.

Other features will become apparent from the following description, drawings, and claims.

### BRIEF DESCRIPTION OF THE DRAWINGS

FIG. 1 is a block diagram of an example of a flash lamp system for use with a conveyor and a continuous motion workpiece..

FIG. 2 shows a representation of a sheet of material.

FIGS. 3, 4 and 6 are views of a user interface.

FIG. 5 is a pictorial illustrating lamp offset.

FIGS. 7 and 8 are graphs of lamp current.

FIG. 9 is a close up of a portion of the user interface.

### DESCRIPTION

The system described here is designed primarily for systems in which a workpiece is provided in a continuous process, e.g., in a sheet, although it could be applied to a continuous motion of individual items, such as spaced apart pieces or material One application is for a process, such as a roll-to-roll process, where a sheet of material is sintered, cured, or otherwise processed by the flash lamps providing energy, whether from visible light, ultraviolet radiation, or infrared radiation. In one example of an implementation, printed electronic circuits are provided as a conductive “ink” with small conductive particles on a low temperature substrate, such as paper or a thin plastic, and the ink is sintered to fuse the conductive particles. This idea of sintering small particles with lamps or lasers has been known for a long time; see, e.g., U.S. Pat. No. 4,151,008.

In the system described here, the system has multiple flash lamps, typically three or more in a one-dimensional array, that can operate on a continuous conveyor. The system could have lamps arranged in a two-dimensional array with rows of lamps aligned or offset.

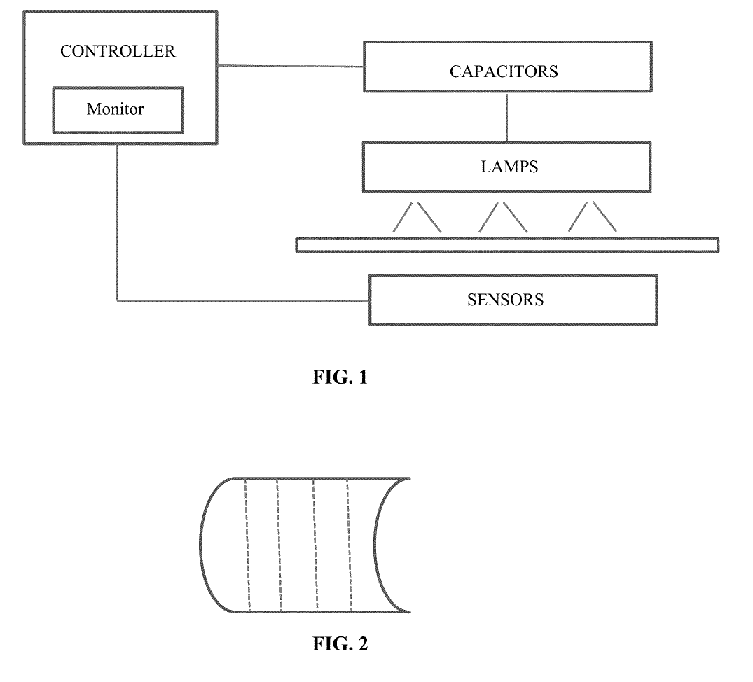

Referring to FIG. 1, a plurality of flash lamps are arranged over a conveyor. A control unit includes a monitor for viewing and for a user interface, and could be a touchscreen for entering parameters. The flash lamps, such as xenon lamps, are driven in a known manner with capacitors for storing energy and a controller for causing the capacitors to provide current to the lamps to flash. An example of a description for how a known lamp is operated is described in U.S. Pat. No. 7,501,773, which is incorporated herein by reference.

The systems described here are designed to provide a desired amount of energy to a sheet of material moving in a continuous manner, such that the material is provided with energy in desired locations, e.g., across a continuous area, and preferably in an efficient manner that provides some margin for error, but is not overly wasteful of energy. Referring to FIG. 2, the sheet material can be imagined to be a series of stripes perpendicular to the lateral motion of the conveyor and having a certain width. The system described here can factor in an overlap parameter such that the energy being provided is twice the width of the stripes, and such that each pulse provides a sufficient amount of energy to the stripe and to half the adjacent stripes. This capability can be useful, for example, if multiple pulses are desired. For example, a first lamp could provide a flash to a first and second stripe; then the next lamp provides a flash to the second and third and the next provides a flash to the third and fourth. In this case, the second and third each get two flashes (and the first and fourth would also receive two flashes with a continuous process). The lamps can flash in any determined order. The processor determines the sequence and timing of the flashing.

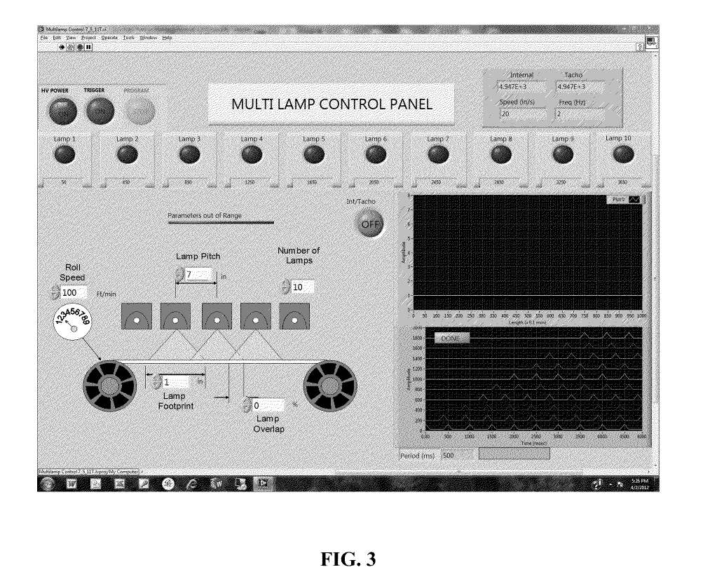

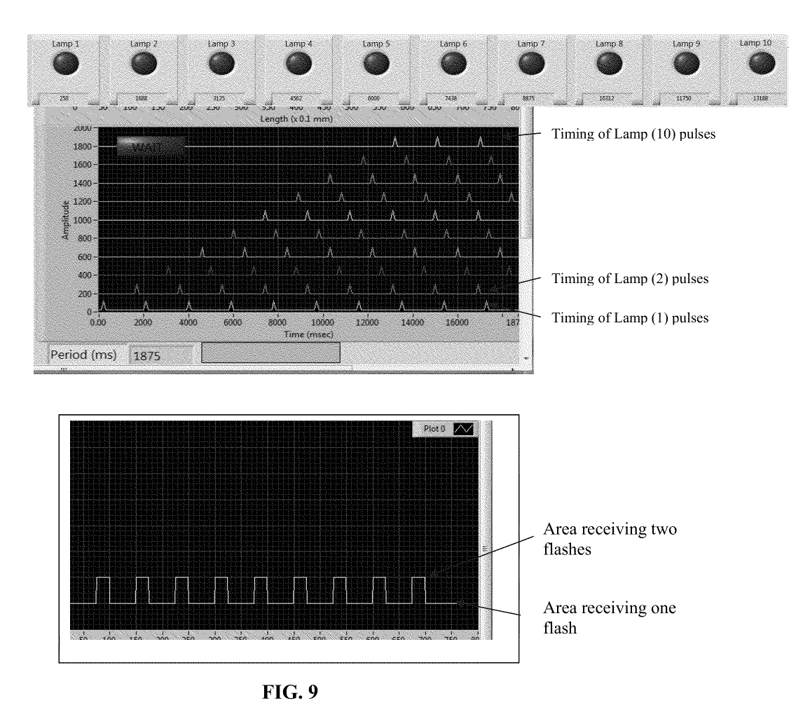

Referring to FIG. 3, an example of a user interface is shown in more detail. This interface illustrates a number of parameters that can be considered in such a control system. The interface has both practical and ornamental aspects, ornamental in that colors can be used, and in the pictorial representations of lamps and parameters. The pictorial representations as shown may not all be to scale (e.g., as shown, the lamp footprint is smaller than the lamp pitch, but appears larger). This user interface includes graphs showing the amplitude over the length of the workpiece (top graph), and a representation of the flashes provided by the lamps over time. These graphs are shown in more detail in FIG. 9.

Some of the terms and parameters that are used in this system include:

Delay (n): a time interval starting when the target material first enters the footprint of lamp(1) and ending when lamp(n) is first flashed.

Frequency: the flash rate expressed in flashes per second (Hz). All lamps are typically pulsed at the same frequency, although they could be different.

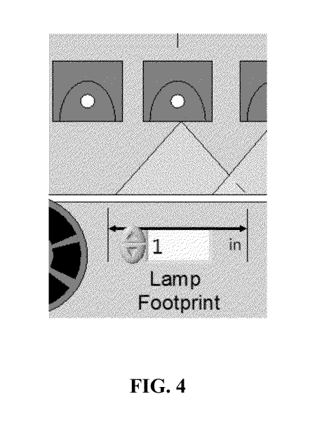

Lamp Footprint: the width of the optical beam created by a single lamp (note that the figures do not show the lamp footprint and the lamp pitch or offset to scale). The width is generally modeled as a Gaussian curve, so some judgment may be used regarding the actual width of the footprint and where that is defined. This determination can be a function of the material and the process; e.g., based on a relationship between the energy that will typically work compared to the peak energy to be used. This part of the user interface is shown in close-up FIG. 4.

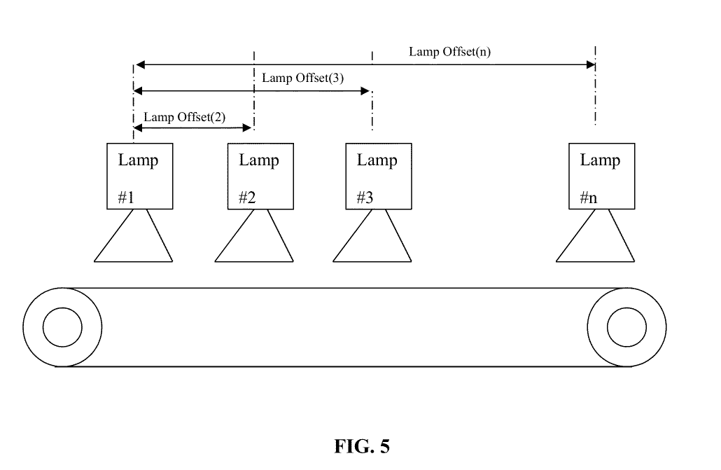

Lamp Offset (n): the distance between the optical centerline of the first lamp to the optical center of the n-th lamp as shown in FIG. 5. Lamp Offset (1)=0.

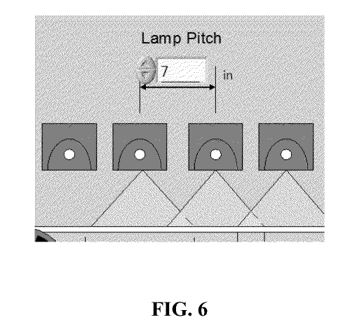

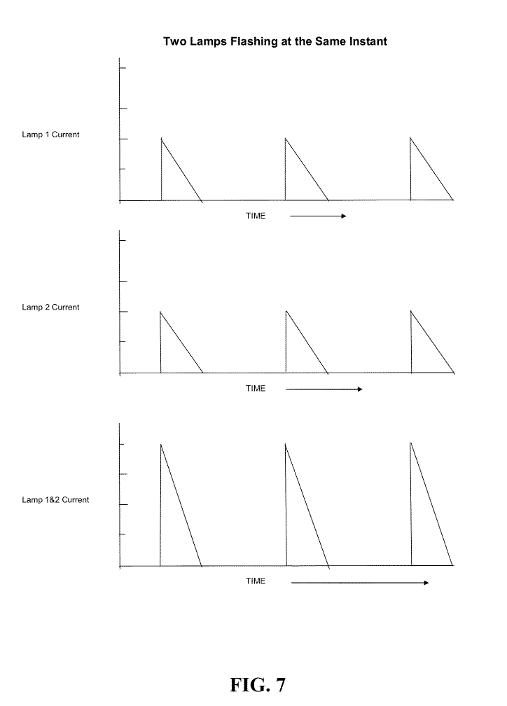

Lamp Pitch: the distance from the optical center of one lamp to the optical center of the adjacent lamp when the optical center of all lamps is equal distance to its nearest neighbor. This is shown in FIG. 6.

Number of Lamps: the quantity of flash lamps being used to in the curing process.

Period: the time interval between consecutive flashes of the same lamp; the period is the inverse of the frequency of flashes.

Roll Speed: the linear velocity of the target material as it transverses under the lamps.

% Lamp Overlap: a measure of the extent that an area on the targeted material is exposed to the light from more than one lamp flash as indicated in the table of examples below:

TABLE 1

| | |
|---|---|
| % Lamp Overlap = 0 | All areas of the targeted material are |
| | exposed to exactly one lamp flash |
| % Lamp Overlap = 0.25 (or 25%) | Half of the targeted material will |
| | receive one flash and half of the |
| | material will receive two flashes |
| % Lamp Overlap = 0.50 (or 50%) | All areas of the targeted material will |
| | be exposed to exactly 2 pulses |
| % Lamp Overlap = 0.75 (or 75%) | All areas of the targeted material will |
| | be exposed to exactly 4 pulses |

Relevant formulas include the following:

Period=1/Frequency (1)

Frequency=(Roll Speed/Number of Lamps)/(1−% Lamp Overlap) (2)

Delay (1)=+Lamp Footprint/Roll Speed (3)

For N>1. Delay (n)=Delay (1)+(Lamp Offset(n)+(Lamp Footprint ×(1−% Lamp Overlap)))/Roll Speed (4)

Delay (n)=Delay (1)+(((n−1)×Lamp Pitch)+(Lamp Footprint ×(1−% Lamp Overlap)))/Roll Speed (5)

There are a number of error conditions. The frequency could be too high. Design limitations determine the maximum frequency any flash lamp can be operated. Limiting parameters include lamp size and shape, gas fill pressure, power supply wattage, lamp cooling, and lamp re-strike times. The system can enable the flash frequency to be calculated and controlled. Potential improper operation can be prevented. A frequency error is provided when Frequency>Max limit.

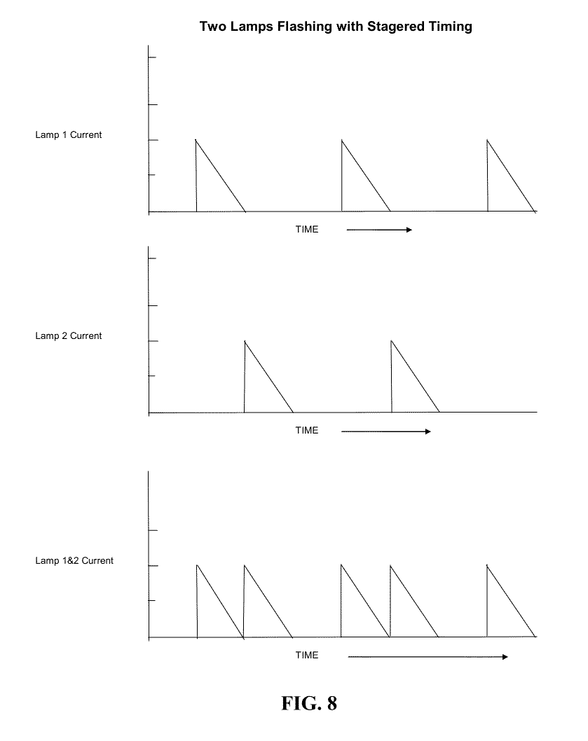

Another error condition can be high line current. Flash lamps operate by charging a capacitor then discharging the current through the lamp. It is generally desirable to charge so that flashing occurs soon after the capacitor is charge. Thus, in an efficient system, there will often be a correlation between the flashing times and the charging times, even though they are not strictly related. If multiple capacitors are being charged at the same time, and therefore also in some cases flashing at the same time, the instantaneous current can be very high. These peak currents can be significantly reduced by staggering the times that the capacitors are charged. The system determines a flash sequence such that the capacitors can be charged and discharged efficiently, without charging capacitors at the same time, and overcurrent conditions can thus be prevented. A high current error is indicated when Delay(n)/period is an integer or very close to an integer value. As shown in FIGS. 7 and 8, the flashing can be staggered, or can be done at the same instant, making it easier to efficiently charge capacitors in a staggered manner as well.

The system can include speed sensors, e.g., a tachometer, to monitor the actual speed of the conveyor, in case it deviates from the expected speed. The controller can make adjustments to the parameters in response, and in some systems, may also control the line speed, which in theory should be as high as the system will allow. Calibration and/or test regions can be provided on the conveyor and/or on the target material and read visually or in some other automated manner to determine that the desired energy is being provided and in the desired places. If read in an automated manner, the data can be fed back to the controller to make adjustments to the flash sequence and/or line speed. Thus as indicated above, the system can sense changes in conditions, such as the line speed or a lamp failure, and automatically make adjustments to the parameters.

The control system described here can enable the use of low frequency pulse lamps for continuous motion processes through determining a frequency, sequence, and timing for the lamps; determine and control the flash sequence of a series lamps to insure uniform processing of the target material; automatically adjust the frequency and flash sequence for variations in conveyor speed, starts and stops; adjust the frequency and flash sequence when one or more lamps are removed for maintenance or an additional lamp is added to the system; identify and avoid high line current conditions; identify and avoid operating conditions that could damage the lamp or power supply; and provide for a desired level of overlap in the area that is flashed.

There are a number of possible advantages of the systems and methods described here. By adding lamps and providing the ability to make adjustments as a result, the production speed can be increased. The production system can be dynamically reconfigured to maintain a level of production when one or more lamps fail; that is, it can adjust the frequency, sequence, and timing of the lamps. This means that processing can continue until a desirable opportunity to replace a lamp while still providing sufficient energy to all desired parts of the workpiece. The production system can also automatically adjust for starts, stops and variations in conveyor speeds through feedback, such as from a tachometer, or from other conditions, such as if a sensor detects a possible flaw in the output. The peak current draw can be reduced by staggering the pulse sequence. The wattage of the individual lamps can be reduced and the life of the individual lamps life extended by using more lamps, each operating at a lower pulse rate, such as at 50 Hz or less (20 flashes per second), or 10 Hz or less (10 flashes per second).

Compared to continuous mercury lamps, these flash lamp systems and methods provide less heat with much higher peak power, which is a generally known benefit of flash lamps. Compared to pseudo-synchronized flash lamp systems, these flash lamp systems and methods can provide a lower peak current draw.

The controller or control system can use any appropriate form of processing, including microcontroller, microprocessor, ASIC, special purpose processor, general purpose computer, group of computers, etc., referred to here generally as a “processor.” The processor communicates with the interface, controls the lamps, and communicates with sensors, such as the tachometer.

For the examples below, pictures of the user display are shown in the incorporated provisional application.

### EXAMPLE 1

Input parameters—Reference Values

Speed: provided from a tachometer on the system=20 ft/min (6 m/min)

### Lamp Pitch=5 in. (12.7 cm)

### Number of Lamps=10

### Lamp Footprint=1 in. (2.54 cm)

### Lamp Overlap=0.25

Outputs include a frequency of 0.5333 Hz, which is less than once per second.

### EXAMPLE 2

In this example, roll speed is doubled compared to Reference (Example 1).

Input parameters:

Speed: provided from a tachometer on the system=40 ft/min (12 m/min)

### Lamp Pitch=5 in. (12.7 cm)

### Number of Lamps=10

### Lamp Footprint=1 in.(2.54 cm)

### Lamp Overlap=0.25

As a result, the frequency is doubled to 1.066667 Hz.

### EXAMPLE 3

In this example, the number of lamps is reduced compared to Reference, causing the frequency of flashes from each lamp to be doubled to 1.06667 Hz.

Input parameters

Speed: provided from a tachometer on the system=20 ft/min (6 m/min)

### Lamp Pitch=5 in.(12.7)

### Number of Lamps=5

### Lamp Footprint=1 in.(2.54 cm)

### Lamp Overlap=0.25

### EXAMPLE 4

In this example, an increase in % Lamp Overlap increases lamp frequency compared to Reference. As a result, the frequency increases to 0.8 Hz.

Input parameters

Speed: provided from a tachometer on the system=20 ft/min

### Lamp Pitch=5 in.

### Number of Lamps=10

### Lamp Footprint=1 in.

### Lamp Overlap=0.50

### EXAMPLE 5

This example indicates a frequency error by trying to turn the conveyor speed too high. Since the parameter values led to a frequency greater than the maximum 10 Hz that the lamp can handle it led to a fault condition indicated by the ‘Parameter out of range’ indication. turning Red. Lamp flashing is inhibited at this time.

Input parameters

Speed: provided from a tachometer on the system=100 ft/min (30 m/min)

### Lamp Pitch=5 in. (12.7 cm)

### Number of Lamps=10

### Lamp Footprint=1 in. (2.54 cm)

### Lamp Overlap=0.25

### EXAMPLE 6

This example demonstrates a high current error. Since the lamps were calculated to flash too close to simultaneously, a ‘Parameter out of range’ indicator goes off (e.g., by turning red).

Input parameters

Speed: provided from a tachometer on the system=30 ft/min (9 m/min)

### Lamp Pitch=7 in. (17.8 cm)

### Number of Lamps=10

### Lamp Footprint=1 in. (2.54 cm)

Lamp Overlap=0.75

1. A flash lamp system for operating on a workpiece that is in the form of a sheet and that is in continuous motion comprising:
a plurality of flash lamps, each of which for providing a flash of energy to the workpiece;
a processor for controlling the flashing of the plurality of flash lamps to ensure that the workpiece sheet receives desired energy over a desired area, the processor controlling the flashing based on parameters including a line speed that the workpiece is moving relative to the flash lamps, the positioning of flash lamps relative to each other, the processor determining a frequency of flashing, and sequence and timing of the flash lamps, and
wherein the processor is responsive to changes in conditions for automatically adjusting parameters used to cause the lamps to flash.

2. The system according to claim 1, wherein the processor is responsive to changes in the line speed for automatically adjusting parameters used to cause the lamps to flash.

3. The system according to claim 1, wherein the processor receives information regarding speed from a tachometer.

4. The system according to claim 1, wherein the processor is responsive to a lamp ceasing to function for automatically adjusting parameters used to cause the lamps to flash including the sequencing and timing for when the lamps flash.

5. The system according to claim 1, wherein the processor is responsive to a lamp ceasing to function for automatically adjusting the line speed.

6. The system of claim 1, wherein the processor causes the lamps to flash at no more than 10 Hz each.

7. The system of claim 1, wherein the processor is responsive to at least the following parameters to causes the lamps to flash: number of lamps, spacing between lamps, and a percent overlap parameter.

8. The system of claim 1, wherein the processor is further responsive to a lamp footprint that indicates an area of a beam created by a lamp.

9. A method comprising:
determining parameters under which a plurality of flash lamps provide energy to a workpiece that is in the form of a sheet and that is in continuous motion such that the workpiece sheet receives desired energy over a desired area, including determining a frequency of flashing and sequence and timing of the flash lamps;
monitoring one or more conditions of operation; and
in response to a change in conditions, automatically re-determining parameters under which a plurality of flash lamps provide energy to the workpiece.

10. The method of claim 9, wherein the monitoring includes monitoring a line speed relating to movement of the workpiece relative to the flash lamps, wherein the change in conditions includes a change in the line speed.

11. The method of claim 9, wherein the monitoring includes determining if a lamp ceases to function, the re-determining allowing the flash lamps to continue automatically to provide sufficient energy to the workpiece without replacing the lamp.

12. The method of claim 9, wherein the re-determining includes altering the sequence and timing of when the lamps flash.

13. The method of claim 9, wherein the lamps flash at no more than 10 Hz each.

14. The method of claim 9, wherein the determining is responsive to at least the following parameters to causes the lamps to flash: number of lamps, spacing between lamps, and a percent overlap parameter.

15. The method of claim 9, wherein the determining is further responsive to a lamp footprint that indicates an area of a beam created by a lamp.

16. The method of claim 9, wherein the flash lamps provide energy to a substrate with leads formed from conductive particles, the energy from the flash lamps for sintering the particles.

17. A flash lamp system for operating on a workpiece that is in the form of a sheet and that is in continuous motion comprising:
a plurality of flash lamps for providing energy to a sheet of material in motion relative to the flash lamps;
a processor for controlling the flashing of the plurality of flash lamps, including determining a frequency of flashing, and sequence and timing of the lamps, the processor determining a frequency based at least in part on a number of lamps, lamp footprint, spacing between lamps, and a percent of lamp overlap.

18. The system of claim 17, wherein the processor indicates an error if the determined frequency exceeds a threshold.

19. The system of claim 19, wherein the processor indicates an error if the determined frequency and a schedule of flashing would cause a current to exceed a threshold.
